(19) United States
(12) Patent Application Publication
(10) Pub. No.: US 2017/0003349 A1
(43) Pub. Date: Jan. 5, 2017

(54) ARC SUPPRESSION AND PROTECTION OF INTEGRATED FLEX CIRCUIT FUSES FOR HIGH VOLTAGE APPLICATIONS UNDER CHEMICALLY HARSH ENVIRONMENTS

(71) Applicant: GM Global Technology Operations LLC, Detroit, MI (US)

(72) Inventors: Evan J. Dawley, Lake Orion, MI (US); Roger M. Brisbane, Washington, MI (US); Cammi L. Siu, Macomb, MI (US)

(21) Appl. No.: 14/790,116

(22) Filed: Jul. 2, 2015

(51) Int. Cl. G01R 31/36; H01M 10/48

(52) U.S. Cl. CPC G01R 31/362; H01M 10/482; G01R 31/3658; H01M 2220/20

(57) ABSTRACT

A battery pack, an integrated device for sensing individual battery voltages in a battery pack and protecting the battery pack in the event of a circuit-breaking event, and a method of forming an integrated voltage-sensing circuit for use in a battery-powered automobile propulsion system. The battery pack includes numerous voltage sensing circuits with patterned sense line trace fuses and an encapsulant formed around each of the fuses. The encapsulant is robust enough to provide environmental isolation of the patterned fuse such that the tendency of the fuse to form short-circuit connections to adjacent circuits is avoided under both normal battery pack operation and after a circuit-breaking episode where the fuse blows.

### BACKGROUND OF THE INVENTION

This invention relates generally to voltage-sensing and protective components used in conjunction with a battery-powered system, and more particularly to a way to increase the environmental resistance of a voltage-sensing fuse that is integrated into a flexible circuit used for voltage monitoring and protection of multiple battery cells that are formed into a larger battery assembly.

Lithium-ion and related batteries are being used in transportation applications as a way to supplement, in the case of hybrid electric vehicles (HEVs), or supplant, in the case of purely electric vehicles (EVs), conventional internal combustion engines (ICEs). The ability to passively store energy from stationary and portable sources, as well as from recaptured kinetic energy provided by the vehicle and its components, makes such batteries ideal to serve as part of a propulsion system for cars, trucks, buses, motorcycles and related vehicular platforms. In one form suitable for automotive applications, individual battery cells are combined into larger assemblies such that the current or voltage is increased to generate the desired power output. In the present context, larger module and pack assemblies are made up of one or more cells joined in series, parallel or both, and include additional structure to ensure proper installation into the vehicle. Although the term “battery pack” is used herein to discuss a substantially complete battery assembly for use in propulsive power applications, it will be understood by those skilled in the art that related terms—such as “battery unit” or the like—may also be used to describe such an assembly, and that either term may be used interchangeably without a loss in such understanding.

One common vehicular form of the battery pack is known as a power battery, while another is known as an energy battery. In the power battery pack variant, the individual cells that make up a battery pack are configured as prismatic (i.e., rectangular) cans that define a rigid outer housing known as a cell case. In the energy battery pack variant, the individual cells are housed in a thinner, flexible prismatic pouch. Both variants can be placed in a facing arrangement (much like a deck of cards) along a stacking axis formed by the aligned plate-like surfaces. In either can or pouch form, positive and negative terminals (or tabs) extend outward from one or more of the cell edges and are spaced from one another to act as contacts for connection of the internally-generated electrical current to a common load or circuit. Regardless of which variant is employed, the enclosure used to contain the stacked individual cells needs to provide secure attachment to and containment within the corresponding vehicle compartment, as well as provide proper electrical connectivity between the cells and the power-consuming electrical loads within the vehicle.

One significant part of the electrical connectivity discussed above is in the form of voltage-sensing circuitry to allow for monitoring and the related detection of abnormal voltage conditions within the various battery cells. In one form, such circuitry further includes fail-safe components, such as a circuit-breaker in the form of a fuse. In a conventional form, the fuse is an “off-the-shelf” component which is surface-mounted (such as through reflow soldering or the like) to pads formed on the underlying circuit board or related element. One difficulty associated with traditional welding, soldering or related joining approaches for such fuses is that they are susceptible to manufacturing variations that may lead to fuses that don't create the necessary circuit-breaking function under the expected voltage surge condition, vehicular impact or other disruptive event. Moreover, because fuses contribute resistance to the voltage sensing circuit, any such variations in fuse manufacturing lead to errors in fuse charge and discharge, which can further hamper operational consistency. Another difficulty with attaching traditional fuses arises out of defects in the joining operations discussed above, as these may lead to inadvertent decoupling of the fuse from the electrically-conductive line or other parts of the voltage sensing circuitry; these problems are especially prevalent in vehicular applications where vibratory loads are high.

A significant problem also arises out of the harsh operating environment to which vehicular fuses are exposed. In particular, conventional fuses have a tendency to be unstable in varying local environmental conditions, especially those involving variations in humidity, temperature, the presence of battery pack coolant or other chemical agents, or the like. The present inventors have determined that an inability to control the effects of such environment may contribute to undesirable formations in the fuse that could additionally hamper its effective use.

Because of these and other problems associated with conventional surface-mount fuses, an alternative approach involves the use of so-called “integrated trace fuses” that are formed as part of the traces that make up the current-routing circuitry. These can act as tunable fusing elements by forming necked-down areas along the trace fuse length through conventional photoetching processes that are also used to form the traces or related lines of the circuit. While the use of an integrated trace fuse configuration can help to provide accurate fuse blow curve characteristics relative to conventional surface-mount fuses, the present inventors have determined that they too suffer from significant setbacks. For example, upon activation of the fuse as a circuit breaker in response to a high voltage (about 400V and above, for instance) circuit-breaking episode or related fusing event, the present inventors have determined that the traces will fuse in a violent manner. More problematic is that such fusing may burn a hole through the circuit's substrate material, which has a tendency to cover the nearby area with conductive carbon that through subsequent dendritic growth into adjacent circuits can lead to other short-circuiting events. The present inventors have determined that such dendritic growth is possible when a conductive film or layer is created that will provide a conductive path from the high voltage circuit to a lower voltage circuit (such as ground), and that such a layer can form by at least two methods, including (a) repeated battery heating and cooling that leads to condensation (which includes both water and various conductive contaminants) inside the battery assembly, and (b) coolant leaks that arise out of various types of failure events. This dendritic formation is particularly problematic in the presence of ionic aqueous deposits (such as from coolant or the like which, like the water mentioned above, may evaporate to leave conductive contaminants behind that can build up and provide the high voltage-to-ground short-circuit). As such, dendritic growth can occur at any point where the sensing circuit is not sealed against such an environment. Furthermore, because battery packs used in vehicular platforms operate predominantly in a dynamic (i.e., non-stationary) environment, the coolant used to keep battery pack temperatures to within prescribed limits can migrate throughout the pack assembly during various maneuvers, such as vehicular cornering, accelerating, hitting pot holes and related undulations, accidents or the like. Conductive condensate can also form on any surface, including the top surface, where hot humid air and cold environments come together.

The present inventors have further determined that the length of the integrally-formed fuse must be long enough to handle the high voltage of the anticipated failure mode. By way of example, they have determined that high-voltage fusing events such as those discussed above in require a greater distance in which to extinguish themselves (especially in an open air environment); this in turn requires more packaging space to accommodate the longer length. Such a configuration may not be feasible in tightly-packed circuit boards, where the space to accommodate longer fuses is at a premium. Furthermore, the present inventors have determined that the use in a voltage-sensing circuit of high resistance wire (such as those that are nickel- or aluminum-based) as a way to avoid the deleterious effects of an arcing event is not effective in that it is still subject to the same variations in resistance as the surface-mounted fuses discussed above. Moreover, the present inventors have determined that when such circuitry is in the presence of a conductive liquid (such as the coolant used to cool the battery pack as discussed above) without suitable environmental protection, these variations can become even more pronounced.

### SUMMARY OF THE INVENTION

In accordance with one aspect of the present invention, an assembly for sensing voltage produced by at least one battery cell within a battery pack is disclosed. The assembly includes a battery interconnect board (ICB) defining numerous busbars thereon, as well as rigid or flexible circuit board cooperative with the ICB. The circuit board includes numerous voltage sensing circuits formed on its surface, where each such circuit includes an integrally-formed fuse (also referred to as a fusible element) as part of an electrically-conductive line or trace. In the present context, an integrally-formed fuse differs from a surface-mounted or discretely-formed one through its method of fabrication. For example, the integrally-formed fuse is preferably formed by a patterning or related deposition process, whereas the discretely-formed version is first manufactured, then attached to the circuit board through the aforementioned welding, soldering or related joining techniques. In one form, the cells may be prismatic pouches, while in another they can be prismatic cans, while in still another they can be cylindrical cans.

In addition to the fuse and line, each voltage sensing circuit includes an encapsulant formed around the fuse with an environmentally resistant material such that each of the voltage sensing circuits is signally cooperative with a respective one of the busbars while keeping the fuse isolated from the ambient environment during both normal battery pack operation and after a circuit-breaking episode where the fuse becomes blown. In the present context, it will be understood that such environmental isolation does not prevent the fuse and trace from permitting the normal flow of electrical current between them and the various battery cell terminals and busbars, but rather that it includes containing the fuse within a shell-like protective covering such that the tendency to form a short-circuit with adjacent circuits through dendritic growth, tracking or related phenomena is eliminated or substantially curtailed. In a preferred form, the encapsulant forms a high-dielectric (i.e., electrically-insulative) covering; this acts to suppress and contain the arc and any debris or carbon created from a fusing event; this containment is particularly helpful in preventing a hole from being burned through the circuit board substrate. Thus, there is no risk of resistive short circuits due to dendritic growth or tracking. Moreover, the encapsulant material is preferably a high viscosity, thixotropic material made for selective dispensing (such as through robotic methods). The coating could be either thermally cured or UV cured, with the latter being preferable since the curing time is much shorter. In one form, the material may be polyurethane-based. The dielectric strength is preferably about 20 kV/mm, while its CTI index is at least 600. In a more particular form, the encapsulant may be made from an intumescent material such as that disclosed in related and commonly-owned U.S. application Ser. No. 14/710,216 that was filed on May 12, 2015 and entitled NOVEL THERMAL PROTECTION SYSTEM FOR POWERED CIRCUIT BOARDS INCLUDING FUSES the contents of which are incorporated by reference in their entirety. As well as preventing resistive shorts from forming across open, fused traces, the addition of the encapsulant is additionally significant in that it enables shorter length fusible trace regions; this is particularly valuable in configurations where larger voltage battery cell and pack configurations are employed. In one preferred form, the encapsulant is a thixotropic material such that it acts like a thick film conformal coating at the very center above the fusible element. This enables it to first form a uniform layer over the integrally-formed fuse, and then to resist additional flow thereafter. In one form, an ink-like deposition process may be used to help the encapsulant rapidly regain its viscosity upon deposition; this is particularly helpful when the encapsulant is formed on opposing sides of the circuit board that corresponds to the placement of the fuse; such dual-sided encapsulant formation better isolates the fuse from the ambient environment. Significantly, the volumetric dimension (including length, width and depth) of the encapsulant may be made such that damage to the blown fuse is substantially limited to local fuse melting after the circuit-breaking episode; in this way, the more violent forms of fuse blowing and concomitant chance to corrupt adjacent circuits is avoided.

In accordance with another aspect of the present invention, a battery pack configured to provide propulsive power to a vehicle is disclosed. The battery pack includes numerous prismatic battery cells aligned along a stacking axis as discussed above, a housing configured to contain the plurality of cells and numerous voltage sensing circuits each of which is electrically cooperative with a respective one of the cells. Each of the circuits include one or more patterned fuses formed within at least a portion of an electrically conductive voltage trace, as well as an encapsulant formed around the fuse. The encapsulant is made from an environmentally resistant material such that the fuse remains isolated from the ambient environment during both normal pack operation, as well as after a circuit-breaking episode that causes one or more of the fuse to blow. It will be appreciated by those skilled in the art that the battery pack may include additional features for mechanical or electrical support, including additional frames, containers, cooling circuits or the like. For example, in a preferred optional form, the voltage sensing circuits form part of an assembly made up of a battery ICB that defines numerous busbars placed on or formed in it, as well as a circuit board cooperative with the ICB, the circuit board (which may be either rigid or flexible) defining the various voltage sensing circuits thereon.

In accordance with yet another aspect of the present invention, a method of providing short circuit protection for an automotive propulsion system battery pack is disclosed. The method includes operating the battery pack made up of numerous prismatic battery cells aligned along a stacking axis to such that they are disposed within a housing to enable numerous voltage sensing circuits that are each cooperative one or more of the cells to pass an electrical current indicative of cell voltage to a patterned fuse formed within at least a portion of an electrically conductive voltage trace. An encapsulant formed around the fuse maintains the fuse in substantial environmental isolation from the ambient environment during levels of the electrical current that correspond to both normal pack operation, as well as after a circuit-breaking episode where the fuse becomes blown.

### BRIEF DESCRIPTION OF THE DRAWINGS

The following detailed description of specific embodiments can be best understood when read in conjunction with the following drawings, where like structure is indicated with like reference numerals and in which:

FIG. 1 is a schematic diagram of an exemplary vehicle configured with a hybrid power source, showing the integration of a battery pack with various other subcomponents of the vehicle;

FIG. 2 is a simplified exploded view of a battery pack that can be used in the vehicle of FIG. 1;

FIG. 3 shows a top perspective view of an ICB that shows fuses incorporated into the voltage sensing circuit between the busbars and terminal pins according to an aspect of the present invention;

FIG. 4 shows a detailed view of the voltage trace portion of the voltage sensing circuit with an overmolded encapsulant, both formed on a portion of the ICB of FIG. 3 according to an embodiment of the present invention; and

FIG. 5 shows an edge-on elevation view of a notional placement of the encapsulant of FIG. 4 both above and below the fuse and a portion of the voltage trace.

### DETAILED DESCRIPTION OF THE PREFERRED EMBODIMENTS

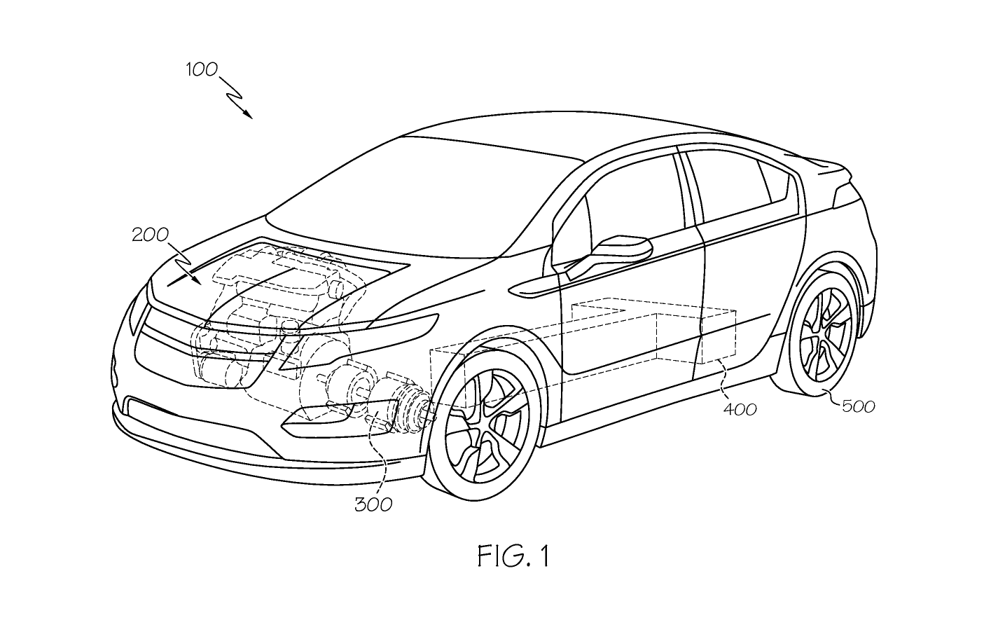

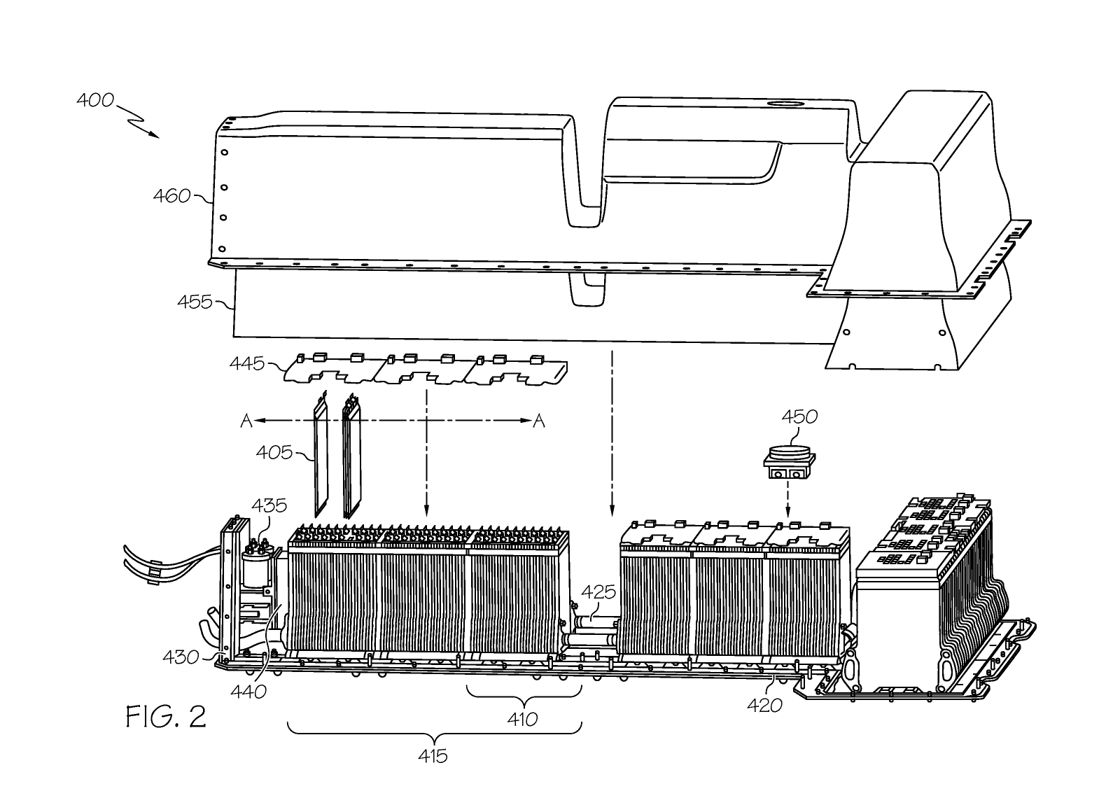

Referring first to FIGS. 1, and 2, views of a hybrid-powered vehicle 100 (FIG. 1) and a battery pack 400 (FIG. 2) used to propel vehicle 100 are shown. Within the present context, it will be appreciated that the term “vehicle” may apply to car, truck, van sport utility vehicle (SUV) or the like. Vehicle 100 includes an ICE 200, one or more electric motors 300 and battery 400 (also referred to herein as battery pack to emphasize the assembled nature of multiple battery cells within), as well as an electronic control system (not shown). Vehicle 100 further includes a powertrain (not shown, which could be in the form of a driveshaft or the like) to deliver propulsive power from the ICE 200, motor/generator 300 or battery 400 to one or more of the wheels 500. Battery 400 may additionally include a state of charge (SOC) system and power inverter assembly (neither of which are shown), the latter of which includes various modules, including those for the IGBT and capacitors (not shown) as well as other conductive elements configured to provide a pathway for current flow between these and other associated battery-related electronic components. Busbar assemblies (portions of which are shown and discussed in more detail below) provide compact, reliable electrical connection between the various cells within the battery pack 400, as well as between the pack 400 and electrical loads throughout the vehicle 100. Although the battery pack 400 is shown in the rear of vehicle 100, it may be located in any suitable location to facilitate a preferred degree of electrical and structural coupling. In one embodiment, battery pack 400 is an assembly made up of numerous lithium ion (Li-ion) cells 405. It will be appreciated by those skilled in the art that while vehicle 100 is presently shown as a hybrid-powered vehicle, that one with purely electric power (i.e., one with no need for ICE 200) is also deemed to be within the scope of the present invention.

Referring with particularity to FIG. 2, details associated with battery pack 400 are shown in a partially-exploded view. The battery pack 400 is typically made from numerous individual cells 405 that may be grouped into larger modules 410. In the present context, the terms “battery cell”, “battery module” and “battery pack” (as well as their shortened variants “cell”, “module” and “pack”) are use to describe different levels of components of an overall battery-based power system, as well as their assembly. For example, numerous individual battery cells 405 are stacked in a face-to-face relationship along a stacking axis A-A such that their edges substantially align to define a generally rectangular shape. These cells 405 form the building blocks of battery modules 410 that in conjunction with ancillary equipment make up the completed battery pack 400. The usage of one or more of such terms will be apparent from the context. Although not shown, other forms of battery cells 405 may be used with the present invention, including prismatic can and cylindrical can variants. The various battery cells 405 and modules 410 may be aligned as shown to be supported by a common tray 420 that can also act as support for coolant hoses 425, headers 430, manifolds or related conduit where supplemental cooling may be desired. Moreover, the modules 415 that may be combined as a group or section 415 and aligned to be supported by common tray 420 that can also act as support for coolant hoses 425 that can be used in configurations where supplemental cooling may be desired. A bulkhead 430 may define a primary support structure that can function as an interface for the coolant hoses 425, as well as house a battery disconnect unit 435 in the event battery service is required. In addition to providing support for the numerous battery modules 410, tray 420 and bulkhead 430 may support other modules, such as a voltage, current and temperature measuring module (VITM) 440 (which acts as a centralized “brain” to aggregate the individual cell voltage information via local networking componentry such as that discussed herein. Placement of individual battery cells 405 (to be discussed in more detail below) within one of battery modules 410 is shown, as is the covering thereof by a voltage and temperature module in the form of ICB 445 that may be made to sit atop each of the three main battery sections 415 that make up the T-shaped pack 400 to communicate cell voltage information to the VITM 440. Other features, such as manual service disconnect 450, insulation 455 and a cover 460 complete the battery pack 400.

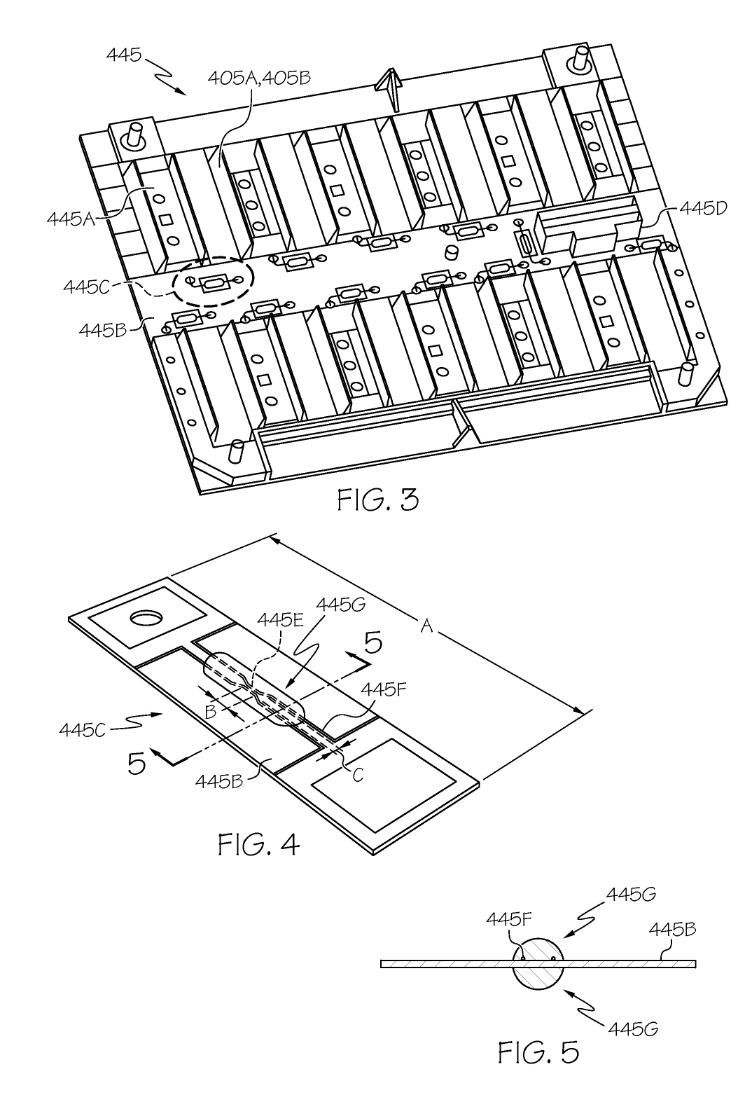

In one typical example, battery pack 400 may include about two hundred to three hundred individual battery cells 405, although (like the arrangement) the number of cells 405 may be greater or fewer, depending on the power needs of the vehicle 100. In a preferred form, the cells 405 define a prismatic construction, while in a more particular form, the cells 405 are of the prismatic pouch variety. Placement of individual battery cells 405 within battery pack 400 is shown, while the ICB 445 (that is discussed in more detail below in conjunction with FIG. 3) may be placed above the aligned cells 405 in order to provide both cell 405 mounting and electrical monitoring and control functions. In a preferred form, the present invention is applied to low current circuits (for example, below 8 amps RMS); however, it will be appreciated by those skilled in the art that it could also be used at higher current levels, and that both such uses are deemed to be within the scope of the present invention.

Referring next to FIGS. 3 and 4, a top perspective view is shown of an ICB 445 (FIG. 3) and a portion of a voltage-sensing circuit 445C that is formed on a circuit board 445B portion (FIG. 4). As discussed above, the ICB 445 is used to provide electrical connectivity between numerous individual battery cells 405 and one or more of the battery disconnect unit 435, VITM 440 or other loads within vehicle 100. In one form, the circuit board 445B may use rivets or similar joints or fasteners to achieve connection between it and busbars 445A, the latter of which (along with header 445D) are used to collect the signals generated by each of the various circuits 445C. In particular, each busbar 445A transfers current received from one or the other of the positive and negative tabs 405A, 405B of one or more of the battery cells 405 to IGBT devices, power diodes or other components that can either convert the cell-generated DC signal to either a single-phase AC signal, or as DC power to a suitable load. Numerous fuses 445E are incorporated into the voltage sensing circuit 445C via their integral formation as part of corresponding voltage traces (or lines) 445F. Slot-shaped apertures formed in the ICB 445 are sized and shaped to be compatible with tabs 405A, 405B that project out of the top of the pouches that make up the individual cells 405; the various busbars 445A are also sized and shaped to facilitate such receipt, and may be formed as part of a generally U-shaped channel to provide connection and mounting surfaces for the upstanding tabs 405A, 405B. The busbar-based approach is generally seen to be advantageous over cabling assemblies because (among other things) it—in addition to providing electrical connectivity—makes it possible to integrate voltage-sensing circuit 445C and related monitoring electronics via compact packaging. Furthermore, its general structure allows all of the terminals that are being used to provide electrical connection among the individual cells 405 to be reliably and repeatably positioned relative to one another through a simple assembly operation. By comparison, a surface-mounting approach of the prior art can be problematic when the physical size of the fuse is large relative to the voltage traces and other circuitry that is placed on or formed in the circuit board or related substrate.

Referring with particularity to FIG. 4, a test coupon representative of one preferable ICB-to-busbar connection—the flex circuit-based approach—shows the formation of the encapsulant 445G over a portion of the voltage-sensing circuit 445C. Because the fuses 445E are small relative to the discrete, surface-mounted variants, and are amenable to being integrally formed onto the circuit board 445B, it is preferable to use a flexible version of the board rather than a rigid one. As such, in a preferred form, the voltage-sensing circuit 445C depicted in the figure shows that a conventional surface-mounted fuse is replaced in the present invention with an integral fuse 445E and encapsulant 445G, with the latter forming a protective shell-like covering over the former. Importantly, the length of the encapsulant 445G (shown presently as an elongate, tubular (in situations where it is deposited on both sides of the circuit board 445B) or semi-tubular (in situations where it is deposited on just the same side of the circuit board 445B as the fuse 445E) is used to cover the fuse 445E and a portion of the adjacent patterned voltage trace 445F for arc suppression and related tracking resistance can be made selectively longer or shorter depending on the size of the fuse 445E. In one form, the fuse 445E and connected voltage trace 445F may be made from a photoetched copper or other electrically-conductive material, while the flexible circuit board 445B is made from a polyethylene naphthalate (PEN) base layer, as well as an optional cover layer. Likewise, the length of the fuse 445E that can be selectively formed as part of the voltage trace 445F may be adjusted, depending on the circuit-breaking needs of the voltage-sensing circuit 445C, and as long as they don't interfere with operation of adjacent circuits.

FIG. 5 shows an edge-on elevation view along the axial length of the voltage sensing circuit 445C with patterned voltage trace 445F and fuse 445E, as well as the placement of the encapsulant 445G both above and below the fuse 445E and adjacent trace 445F. In a preferred form, the encapsulant 445G can be dispensed and cured on both sides of the flexible circuit board 445B to offer the most robust protection of the fuse 445E. As mentioned above, the encapsulant 445G may assume any shape and size required to provide adequate environmental isolation of the fuse 445E; the version depicted in FIGS. 4 and 5 shows that the encapsulant 445G may form a pair of axially elongate hemispheres situated on opposing sides of the circuit board 445B, while the fuse 445E is formed on the top side of the flexible circuit board 445B. The design objective for the encapsulation and related containment of the fuses 445E that make up the voltage-sensing circuits 445C that are formed on the circuit board 445B that is coupled to or formed as part of ICB 445 is to permit a specific localized section of the circuit that is nearest to the fuse 445E to heat up to the point that the conductive material of the fuse 445E melts, causing the respective circuit to open. As such, the various dimensions of encapsulant 445G may be tailored to the particular circuit-breaking and packaging needs. For example, dimensions pertaining to the encapsulant 445G may be based on voltage trace thicknesses and widths as dictated by the needs of the underlying circuit, as well as the needed resistance to arc formation or the like. Significantly, the encapsulant dimensions determine the resistance of the circuit, and can also be correlated to the amount of heat generated; this latter value may be significant in determining how much heat conduction into the surrounding traces can be expected.

The table below provides some actual thicknesses and dimensions of specimens that were tested at both low (i.e., 4 volts) and mid-range (i.e., 53 volts) voltage levels, as well as the time it took for the circuits to open (i.e., blow time) in seconds. Within the present context, this time-to-failure value was the variable used to measure various design's effectiveness. In the tests, the voltage was applied to the test specimen (in the form of the test coupon that includes the voltage-sensing circuit 445C); during this time, the current was controlled until the circuit was consumed, resulting in the formation of the blown/open circuit.

| COUPON PROPERTIES | | | | | VOLTAGE = 4 V | | | | VOLTAGE = 53 V | | | |
|---|---|---|---|---|---|---|---|---|---|---|---|---|
| SAMPLE | CU | DIMENSION | DIMENSION | DIMENSION | 10.24 | 16 | 25 | 50.41 | 10.24 | 16 | 25 | 50.41 |
| SET | (MICRONS) | A | B | C | 3.2 | 4 | 5 | 7.1 | 3.2 | 4 | 5 | 7.1 |
| 1 | 36 | 34 | 10 | 0.127 | 96 | 1.893 | 0.629 | | 146 | 2.245 | 0.672 | 0.368 |
| 2 | 36 | 42 | 18 | 0.127 | 2.7 | 1.7 | 0.515 | 0.163 | 4.218 | 0.667 | 0.359 | 0.177 |
| 3 | 36 | 34 | 10 | 0.2032 | 91 | 95.5 | 2.46 | 0.371 | 71.1 | 71 | 5.22 | 0.177 |
| 4 | 36 | 42 | 18 | 0.2032 | 90 | 5.8 | 2 | 0.551 | 71 | 4.03 | 1.44 | 0.548 |
| 5 | 36 | 34 | 10 | 0.254 | 70.1 | 156 | 93 | 0.828 | 70.8 | 70.4 | 5.51 | 0.966 |
| 6 | 36 | 42 | 18 | 0.254 | 90 | 90 | 3.98 | 0.815 | 71.232 | 1.441 | 3.64 | 0.548 |
| 7 | 36 | 34 | 10 | 0.3048 | 90 | 90 | 90 | 3.9 | 72 | 72 | 72 | 2.46 |
| 8 | 36 | 42 | 18 | 0.3048 | 90 | 90 | 47.6 | 1.56 | 72 | 72 | 7.91 | 1.325 |

Dimensions A, B and C (all in millimeters, mm) from the table above correspond to those shown with particularity in FIGS. 4 and 5, where A represents the overall length of the test coupon that includes the voltage-sensing circuit 445C, B represents the length of the fuse 445E portion of the trace 445F and C represents the width of the fuse 445E portion of the trace 445F. The top two rows of the two voltage levels depicted in the table correspond to categories for the current, where the topmost row is the current level squared (shown for reference), while the one below it is for the current in amps (which was directly measured experimentally for the data shown therein). It is desirable to show both values because the fusing characteristic is typically characterized by the product of current squared and time. In one form, the data shows that there is a correlation of time-to-failure and the conductor width. In fact, with conductors wider than 0.127 mm, the fuse performance was frequently found to be far in excess of what is required. Another finding for the data is that the length of the conductor is also correlated to ability to carry current. From this, the present inventors are of the belief that heat dissipation is affected by length of the conductor. The present inventors are further of the belief that relying upon the width and length parameters (as well the choice of encapsulant material) is extendable to higher voltage regimes (for example, up to about 400 volts), although arcing and trace material consumption concerns may present some additional challenges regarding self-extinguishment at these higher voltage levels. Even with these additional concerns, the present inventors have found from limited testing at the 400 volt level that a fuse 445E width of 0.127 mm performed acceptably by blowing well in advance of the requirements for contemplated high voltage applications. As such, the protective coating discussed herein is useful to both protect the fuse 445E from the environment, as well as to help suppress arcing behavior, especially where it is most needed at higher voltage levels as a way to establish more reliable fusing characteristics.

It is noted that terms like “preferably,” “commonly,” and “typically” are not utilized herein to limit the scope of the claimed invention or to imply that certain features are critical, essential, or even important to the structure or function of the claimed invention. Rather, these terms are merely intended to highlight alternative or additional features that may or may not be utilized in a particular embodiment of the present invention. Likewise, for the purposes of describing and defining the present invention it is noted that the term “substantially” is utilized herein to represent the inherent degree of uncertainty that may be attributed to any quantitative comparison, value, measurement, or other representation. The term is also utilized herein to represent the degree by which a quantitative representation may vary from a stated reference without resulting in a change in the basic function of the subject matter at issue.

For the purposes of describing and defining the present invention it is noted that the terms “battery”, “battery pack” or the like are utilized herein to represent a combination of individual battery cells used to provide electric current, preferably for vehicular, propulsive or related purposes. Furthermore, variations on the terms “automobile”, “automotive”, “vehicular” or the like are meant to be construed generically unless the context dictates otherwise. As such, reference to an automobile will be understood to cover cars, trucks, buses, motorcycles and other similar modes of transportation unless more particularly recited in context.

Having described the invention in detail and by reference to specific embodiments thereof, it will be apparent that modifications and variations are possible without departing from the scope of the invention defined in the appended claims. More specifically, although some aspects of the present invention are identified herein as preferred or particularly advantageous, it is contemplated that the present invention is not necessarily limited to these preferred aspects of the invention.

What is claimed is:

1. An assembly for sensing voltage produced by at least one battery cell within a battery pack, said assembly comprising:
a battery interconnect board defining a plurality of busbars thereon; and
a circuit board cooperative with said battery interconnect board, said circuit board defining a plurality of voltage sensing circuits comprising at least one patterned fuse formed within at least a portion of an electrically conductive voltage trace such that each of said voltage sensing circuits is signally cooperative with a respective one of said busbars, and an encapsulant formed around said fuse, said encapsulant configured with an environmentally resistant material such that said fuse remains isolated from the ambient environment during both normal battery pack operation and after a circuit-breaking episode where said fuse becomes blown.

2. The assembly of claim 1, wherein said circuit board comprises a rigid circuit board.

3. The assembly of claim 1, wherein said circuit board comprises a flex circuit board.

4. The assembly of claim 1, further comprising a sensing circuit connection header affixed to said battery interconnect board, said header defining a termination point for each of said voltage sensing circuits within said circuit board.

5. The assembly of claim 1, wherein said encapsulant is made from a high dielectric material.

6. The assembly of claim 5, wherein said high dielectric material is at least about 20 kV/mm.

7. The assembly of claim 1, wherein said circuit board is fixedly attached to said battery interconnect board.

8. The assembly of claim 1, wherein said encapsulant is formed on both sides of said circuit board that corresponds to a location where said fuse is situated thereon.

9. The assembly of claim 1, wherein a volumetric dimension of said encapsulant is sized to substantially limit said blown fuse to local melting thereof after said circuit-breaking episode.

10. A battery pack configured to provide propulsive power to a vehicle, said battery pack comprising:
a plurality of battery cells aligned along a stacking axis to define a facing relationship thereby;
a housing configured to contain said plurality of cells therein; and
a plurality of voltage sensing circuits cooperative with a respective one of said plurality of cells and each comprising:
at least one patterned fuse formed within at least a portion of an electrically conductive voltage trace; and
an encapsulant formed around said fuse, said encapsulant configured with an environmentally resistant material such that said fuse remains isolated from the ambient environment during both normal operation of said pack and after a circuit-breaking episode where said fuse becomes blown.

11. The battery pack of claim 10, wherein said plurality of voltage sensing circuits form part of an assembly comprising a battery interconnect board defining a plurality of busbars thereon, and a circuit board cooperative with said battery interconnect board, said circuit board defining said plurality of voltage sensing circuits thereon.

12. The battery pack of claim 11, wherein said encapsulant is made from a high dielectric material.

13. The battery pack of claim 12, wherein said encapsulant is formed on both sides of said circuit board that corresponds to a location where said fuse is situated thereon.

14. The battery pack of claim 13, wherein a volumetric dimension of said encapsulant is sized to substantially limit said blown fuse to local melting thereof after said circuit-breaking episode.

15. The battery pack of claim 10, wherein said plurality of battery cells define a prismatic shape.

16. A method of providing short circuit protection for an automotive propulsion system battery pack, said method comprising:
operating said battery pack which comprises:
a plurality of battery cells aligned along a stacking axis to define a facing relationship thereby;
a housing configured to contain said plurality of cells therein; and
a plurality of voltage sensing circuits cooperative with a respective one of said plurality of cells;
passing an electrical current indicative of a voltage in at least one of said cells to a patterned fuse formed within at least a portion of an electrically conductive voltage trace; and
having an encapsulant formed around said fuse in order to maintain said fuse in substantial environmental isolation from the ambient environment during levels of said electrical current that correspond to both normal operation of said pack and after a circuit-breaking episode where said fuse becomes blown.

17. The method of claim 16, wherein said plurality of voltage sensing circuits form part of an assembly comprising a battery interconnect board defining a plurality of busbars thereon, and a circuit board cooperative with said battery interconnect board, said circuit board defining said plurality of voltage sensing circuits thereon.

18. The method of claim 17, wherein said encapsulant is made from a high dielectric material.

19. The method of claim 17, wherein said encapsulant is formed on both sides of said circuit board that corresponds to a location where said fuse is situated thereon.

20. The method of claim 17, further comprising sizing a volumetric dimension of said encapsulant such that damage to said blown fuse is substantially limited to local melting thereof after said circuit-breaking episode.
